(19) United States
(12) Patent Application Publication
(10) Pub. No.: US 2019/0369487 A1
(43) Pub. Date: Dec. 5, 2019

(54) QD HYDROGEL, QD PATTERNING METHOD, AND QD TRANSFER PRINTING METHOD

(71) Applicant: Shenzhen China Star Optoelectronics Technology Co. Ltd., Shenzhen (CN)

(72) Inventors: Miao Zhou, Shenzhen (CN); Dongze Li, Shenzhen (CN)

(73) Assignee: Shenzhen China Star Optoelectronics Technology Co. Ltd., Shenzhen (CN)

(21) Appl. No.: 16/312,997

(22) PCT Filed: Sep. 18, 2018
(86) PCT No.: PCT/CN2018/106339

§ 371 Date: Dec. 21, 2018

(30) Foreign Application Priority Data
May 30, 2018 (CN) 201810539831.4

(51) Int. Cl. G03F 7/00; G02B 5/20; C09K 11/02; C09K 11/88; C09K 11/74; C08J 9/28; C08J 9/40

(52) U.S. Cl. CPC G03F 7/0002; G02B 5/207; C09K 11/02; C09K 11/883; B82Y 10/00; C08J 9/28; C08J 9/40; C08J 2333/26; C09K 11/7492

(57) ABSTRACT

The present invention teaches a QD hydrogel, a QD patterning method, and a QD transfer printing method. The QD transfer printing method includes the following steps. Step 10: forming a QD hydrogel by loading QD material in a hydrogel material capable of resisting high temperature; step 20: forming a film of the QD hydrogel on a metallic substrate; and step 30: covering the QD hydrogel film by a patterning mold conducting nano imprinting, and obtaining a patterned QD hydrogel film. The hydrogel of the present invention has a lower cost and a high utilization, and is appropriate for industrial production. The QD hydrogel of the present invention guarantees a maximum coverage for QD surface ligand and lowers the QD fluorescence loss in the manufacturing process. When applied to a QD CF sheet, its fluorescent efficiency may be enhanced.

### FIELD OF THE INVENTION

The present invention is generally related to the field of display technology, and more particularly to a quantum dot (QD) hydrogel, a QD patterning method, and a QD transfer printing method.

### BACKGROUND OF THE INVENTION

Quantum dots (ODs) are ultra-small semiconductor particles capable of direct bandgap transition lighting, and have quantum size effect. More common QDs are binary, multi-component, doped, core-shell nanoparticles of group II-VI, II-V, III-V, I-III-VI, etc. They have narrow fluorescent emission peak, pure chroma, high brightness, and superior stability. Therefore, QDs are widely applied to various fields such as lighting, display, laser, bioluminescent labelling, etc.

The application of QDs to display technology is a hot topic in the last decade. Currently, there are QD film, QD photoresist (QDPR), QD ink, etc. The objectives of these applications are to improve optical properties, enhance the brightness and gamut, and to lower energy consumption of display devices using the advantages of QDs such as high fluorescent efficiency and narrow emission spectrum.

Applying QDs to the color filter (CF) substrate is mainly through a QDPR lithography process or QD ink-jet printing (IJP) technique to pattern QDs. As the QDPR lithography process requires curing by ultra-violet (UV) and the use of initiator would increase surface defects of QDs, thereby affecting the fluorescence efficiency. The introduction of some solutions in adjusting the viscosity of QD ink may cause QDs to cluster or block the nozzle. Therefore, the applicability of QD CF substrate is limited.

### SUMMARY OF THE INVENTION

Therefore, an objective of the present invention is to teach a QD hydrogel, a QD patterning method, and a QD transfer printing method. The QDs are wrapped in the pores of the hydrogel microspheres, thereby protecting the QD surface ligand and enhancing QD optical stability so that QD is suitable for industrial production.

To achieve the objective, the present invention teaches a QD patterning method, including the following steps.

Step 10: forming a QD hydrogel by loading QD material in a hydrogel material capable of resisting high temperature.

Step 20: forming a film of the QD hydrogel on a metallic substrate.

Step 30: covering the QD hydrogel film by a patterning mold, conducting nano imprinting, and obtaining a patterned QD hydrogel film.

The hydrogel material comprises one of more polyacrylamide and derivatives of polyacrylamide.

The hydrogel material is P(AM-SSS-NVP), where AM is acrylamide, SSS is sodium p-styrenesulfonate, and NVP is N-vinylpyrrolidone.

The QD material comprises a luminescent core and an inorganic protective shell; the luminescent core comprises one or more green-light materials ZnCdSe₂, InP, and Cd₂SSe, or one or more red-light materials CdSe, Cd₂SeTe, and InAs; and the inorganic protective shell comprises one or more materials CdS, ZnSe, ZnCdS₂, ZnS, ZnO.

The step 10 comprises
dewatering the hydrogel material;
loading QD material in the hydrogel material; and
purifying the hydrogel material loaded with QD material.

The present invention also teaches a QD transfer printing method, comprising
attaching an upper substrate having a patterned hydrogel film to a color filter (CF) substrate; and
instantly heating the upper substrate to a high temperature so that the QD hydrogel film is separated from the upper substrate.

Banks are formed in advance on the CF substrate using lithography.

The CF substrate is further flattened.

The QD hydrogel film is red or green QD hydrogel film.

The present invention also teaches a QD hydrogel, comprising a hydrogel capable of resisting high temperature, and QDs loaded in the high-temperature-resistant hydrogel.

As described above, the QD hydrogel, the QD patterning method, and the QD transfer printing method of the present invention use a hydrogel material having a lower cost and a high utilization, therefore appropriate for industrial production. The QD hydrogel of the present invention guarantees a maximum coverage for QD surface ligand and lowers the QD fluorescence loss in the manufacturing process. When applied to a QD CF sheet, its fluorescent efficiency may be enhanced.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a schematic diagram showing the process of loading QDs in the hydrogel according to an embodiment the present invention.

FIG. 2 is a flow diagram showing a QD patterning method according to an embodiment the present invention.

FIG. 3 shows a process of QD patterning by the method of FIG. 2.

FIG. 4 shows a process of QD transfer printing by a method according to an embodiment of the present invention.

### DETAILED DESCRIPTION OF PREFERRED EMBODIMENTS

The present invention teaches a QD hydrogel mainly including a hydrogel material capable of resisting high temperature, and QDs loaded in the hydrogel material. The hydrogel material may be polyacrylamide (PAM) or hydrogel-like microspheres, film, etc., of its derivatives. The temperature resistance capability of a temperature sensitive hydrogel molecules may be enhanced by introducing bulky side group, charged radical, sulfonic acid-containing monomer, hydrophobic monomer, etc. The hydrogel selected by the present invention preferably has a decomposition temperature greater than 300 degrees Celsius. Adding methylbenaene and petroleum ether of appropriate amounts in the oil phase in the suspension polymerization process may achieve porous polymeric microspheres.

An embodiment of the present invention uses a high-temperature-resistant hydrogel P(AM-SSS-NVP) for loading QDs. Microspheres of the hydrogel may be formed using a suspension polymerization process with acrylamide (AM), sodium p-styrenesulfonate (SSS), and N-vinylpyrrolidone (NVP) as materials. The molecular equation of the hydrogel is as follows.

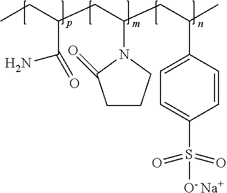

The QD material of the present invention includes a luminescent core and an inorganic protective shell. The luminescent core includes one or more green-light materials ZnCdSe₂, InP, and Cd₂SSe, or one or more red-light materials CdSe, Cd₂SeTe, and InAs. The inorganic protective shell includes one or more materials CdS, ZnSe, ZnCdS₂, ZnS, ZnO.

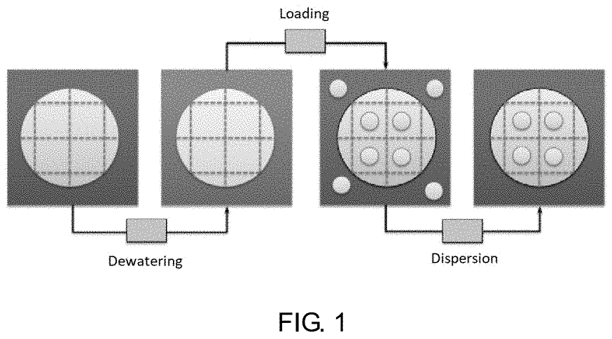

FIG. 1 is a schematic diagram showing the process of loading QDs in the hydrogel according to an embodiment the present invention. The present invention teaches a manufacturing method for QD hydrogel which involves using a hydrogel for loading QDs. The present invention mainly relies on the photoluminescence properties of QD materials and the fillability, high-temperature resistance, and drug resistance of hydrogel material such as P(AM-SSS-NVP), so as to achieve enhanced optical stability for the QDs.

The loading process mainly involves three steps: dewatering the hydrogel, loading the QDs in the hydrogel, and purifying the QD hydrogel.

In one embodiment, P(AM-SSS-NVP) is used as the QD-loading hydrogel. Specifically, the process includes the following steps.

Firstly, the hydrogel microspheres are immersed in tetrahydrofuran (THF), stirred for an hour, and centrifuged. After removing supernatant, they are immersed in the THF again. The process is repeated three times. They are placed overnight in the THF to ensure complete dewatering.

Then, the hydrogel microspheres are dried by the centrifugation of a centrifuge, wetted by a small amount of THF, added with QD material, immersed in chloroform, and stirred for 24 hours. At this point, the QD material is loaded into the hydrogel microspheres.

Finally, the hydrogel microspheres undergo the centrifugation by a 4000 r/min centrifuge for 10 minutes. After removing supernatant, the nano microspheres loaded with QDs are purified.

The QD hydrogel of the present invention have the QDs filled in the hydrogel microspheres. The stability of organic ligand on the QD surface is maintained. The acid-base stability is enhanced. The original superior optical properties are guaranteed. By wrapping QDs in the pores of hydrogel microspheres, the present invention has the surface ligand of QDs protected, guaranteeing a maximum coverage for QD surface ligand and lowering the QD fluorescence loss in the manufacturing process.

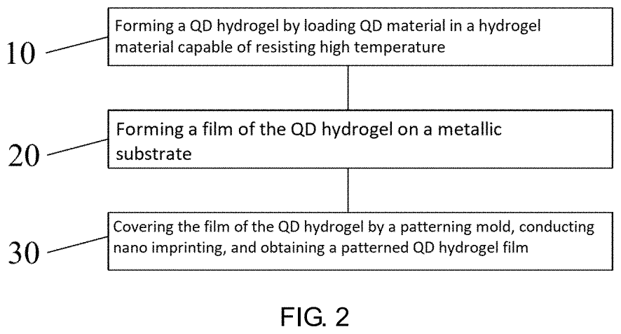

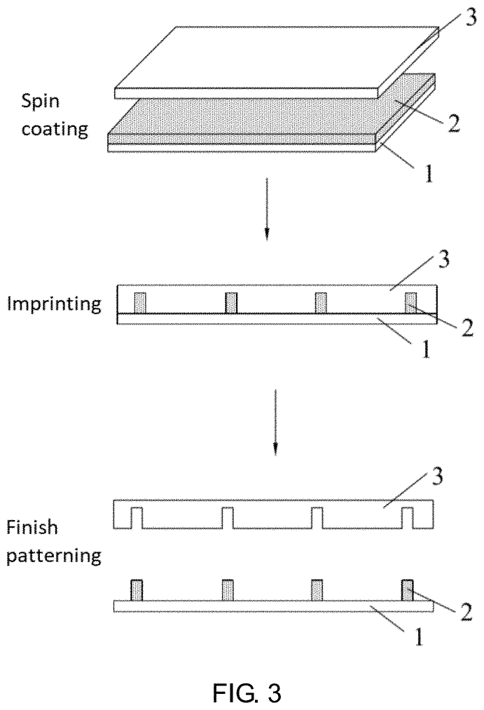

FIG. 2 is a flow diagram showing a QD patterning method according to an embodiment the present invention. FIG. 3 shows a process of QD patterning by the method of FIG. 2. As illustrated, the method includes the following steps.

Step 10: forming a QD hydrogel by loading QD material in a hydrogel material capable of resisting high temperature.

The process is described in details above.

Step 20: forming a film of the QD hydrogel on a metallic substrate.

As shown in FIG. 2, the substrate 1 is made of a metallic material, and is mainly for a subsequent heating process in lifting the patterned QD hydrogel. The film forming process is specifically as follows: spin-coating a dispersion of QD hydrogel microspheres on the metallic substrate 1, and obtaining the QD hydrogel film 2 by volatilization at 100 degrees Celsius.

Step 30: covering the QD hydrogel film by a patterning mold, conducting nano imprinting, and obtaining a patterned QD hydrogel film.

Specifically, as shown in FIG. 3, the patterning model 3 (i.e., upper substrate) covers a top side of the QD hydrogel film 2, and the nano imprinting process is conducted.

In addition to the above method for obtaining the patterned QD hydrogel film, the present invention also teaches a QD transfer printing method, which involves the following steps. Firstly, an upper substrate having a patterned QD hydrogel film is attached to a CF substrate. Then, the upper substrate is instantly heated by high temperature so as to separate the QD hydrogel film from the substrate. The patterned QD hydrogel film may be a red or green QD hydrogel film, or other QD hydrogel film.

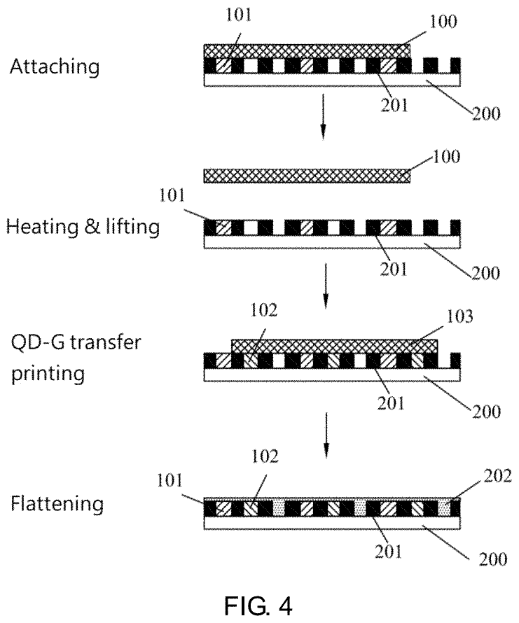

FIG. 4 shows a process of QD transfer printing by a method according to an embodiment of the present invention. As shown in FIG. 4, the QD transfer printing method includes the following steps.

The first step is attaching an upper substrate 100 having a patterned red QD (QD-R) hydrogel film 101 to a CF substrate 200 with banks 201 formed in advance using lithography.

The second step is instantly heating the upper substrate (metallic material) 100 to a high temperature at least 250 degrees Celsius, where the QD-R hydrogel film 101 is separated from the upper substrate 100 and transfer-printed to the CF substrate 200.

The third step is attaching an upper substrate 103 having a patterned green QD (QD-G) hydrogel film 102 to the CF substrate 200, and following the same process to transfer-print the QD-G hydrogel film 102 to the CF substrate 200.

The final step is flattening the CF substrate 200 and obtaining a flat layer 201.

The QD hydrogel, the QD patterning method, and the QD transfer printing method of the present invention use nano imprinting to pattern the hydrogel, and transfer-print the patterned QD hydrogel by loading QDs in porous hydrogel. The hydrogel of the present invention has a lower cost and a high utilization, and is appropriate for industrial production. The QD hydrogel of the present invention guarantees a maximum coverage for QD surface ligand and lowers the QD fluorescence loss in the manufacturing process. When applied to a QD CF sheet, its fluorescent efficiency may be enhanced.

The QD hydrogel, the QD patterning method, and the QD transfer printing method of the present invention involve a porous hydrogel material for QD loading and transfer printing. First, a highly stable QD hydrogel polymeric material is manufactured utilizing the QD loading capability of hydrogel material. Then, nano imprinting is used to pattern QD hydrogel film coated on a substrate. The substrate with the patterned QD hydrogel film is then attached to a CF substrate. The substrate is finally lifted to transfer-print the QD hydrogel film onto the CF substrate.

The QD hydrogel, the QD patterning method, and the QD transfer printing method of the present invention are not only applicable to QD material, but also applicable to gels of other nano material (Au, Ag, Cu, or other oxide, semiconductor gel of nano material). It should be understood that the above described QD material may be replaced by gels of other nano material such as Au, Ag, Cu, etc. metallic nano particles, other oxide nano particles, or semiconductor gel of nano material. The present invention therefore also teaches nano material hydrogel, its manufacturing method, patterning method, and transfer printing method. The nano material hydrogel mainly includes hydrogel material capable of resisting high temperature, and nano material loaded by the high-temperature-resistant hydrogel material. The nano material hydrogel may also be patterned and transfer-printed as taught by the present invention.

As described above, the QD hydrogel, the QD patterning method, and the QD transfer printing method of the present invention use a hydrogel material having a lower cost and a high utilization, therefore appropriate for industrial production. The QD hydrogel of the present invention guarantees a maximum coverage for QD surface ligand and lowers the QD fluorescence loss in the manufacturing process. When applied to a QD CF sheet, its fluorescent efficiency may be enhanced.

Above are embodiments of the present invention, which does not limit the scope of the present invention. Any equivalent amendments within the spirit and principles of the embodiment described above should be covered by the protected scope of the invention.

What is claimed is:

1. A quantum dot (QD) patterning method, comprising
Step 10: forming a QD hydrogel by loading QD material in a hydrogel material capable of resisting high temperature;
Step 20: forming a film of the QD hydrogel on a metallic substrate; and
Step 30: covering the film of the QD hydrogel by a patterning mold, conducting nano imprinting, and obtaining a patterned QD hydrogel film.

2. The QD patterning method according to claim 1, wherein the hydrogel material comprises one of more polyacrylamide and derivatives of polyacrylamide.

3. The QD patterning method according to claim 1, wherein the hydrogel material is P(AM-SSS-NVP), where AM is acrylamide, SSS is sodium p-styrenesulfonate, and NVP is N-vinylpyrrolidone.

4. The QD patterning method according to claim 1, wherein the QD material comprises a luminescent core and an inorganic protective shell; the luminescent core comprises one or more green-light materials ZnCdSe₂, InP, and Cd₂SSe, or one or more red-light materials CdSe, Cd₂SeTe, and InAs; and the inorganic protective shell comprises one or more materials CdS, ZnSe, ZnCdS₂, ZnS, ZnO.

5. The QD patterning method according to claim 1, wherein step 10 comprises
dewatering the hydrogel material;
loading QD material in the hydrogel material; and
purifying the hydrogel material loaded with QD material.

6. A QD transfer printing method, comprising
attaching an upper substrate having a patterned hydrogel film to a color filter (CF) substrate; and
instantly heating the upper substrate to a high temperature so that the QD hydrogel film is separated from the upper substrate.

7. The QD transfer printing method according to claim 6, further comprising:
forming banks in advance on the CF substrate using lithography.

8. The QD transfer printing method according to claim 6, further comprising:
flattening the CF substrate.

9. The QD transfer printing method according to claim 6, wherein the QD hydrogel film is red or green QD hydrogel film.

10. A QD hydrogel, comprising a hydrogel capable of resisting high temperature, and QDs loaded in the high-temperature-resistant hydrogel.
